(19) United States
(12) Patent Application Publication
(10) Pub. No.: US 2024/0409800 A1
(43) Pub. Date: Dec. 12, 2024

(54) HEAT SPREADER MATERIAL

(71) Applicant: ArcelorMittal, Luxembourg (LU)

(72) Inventors: Cristina BLANCO ROLDAN, El Entrego, Asturias (ES); Abel ALVAREZ-ALVAREZ, Oviedo, Asturias (ES); David NORIEGA PEREZ, Oviedo, Asturias (ES); Jorge RODRIGUEZ GARCIA, Gijon, Asturias (ES); Marcos PEREZ RODRIGUEZ, Cangas Del Narcea, Asturias (ES); Roberto SUAREZ SANCHEZ, Avilés, Asturias (ES)

(21) Appl. No.: 18/701,558

(22) PCT Filed: Sep. 1, 2022
(86) PCT No.: PCT/IB2022/058224

§ 371 Date: Apr. 15, 2024

(30) Foreign Application Priority Data
Oct. 19, 2021 (WO) PCT/IB2021/059607

(51) Int. Cl. C09K 5/14; B32B 7/12; B32B 9/00; B32B 9/04; C04B 37/00; H01L 23/373

(52) U.S. Cl. CPC C09K 5/14; B32B 7/12; B32B 9/007; B32B 9/04; C04B 37/008; C04B 2237/363; H01L 23/3735

(57) ABSTRACT

A method for manufacturing a heat spreader including the steps of i. depositing an adhesive on a major surface of at least one graphite layer, to obtain at least one graphite layer coated by an adhesive layer, wherein ii. positioning the at least one graphite layer coated by an adhesive layer on top of each other so as to form a first stack of layers alternating graphite layer and adhesive layer iii. positioning a graphite layer having a thickness from 10 to 200 μm, on the first stack of layers so as to form a second stack of layers, having a graphite layer as top and bottom layers iv. compressing the second stack of layer with a pressure from 7 to 20 MPa to form a graphite-based laminate, v. heating the graphite-based laminate such that the solvent of the adhesive is removed.

This invention relates to a method for manufacturing a graphite laminate, to a graphite laminate and its use in a heat spreader device. Such a heat spreader device can be used, for dissipating the heat and preventing an excessive temperature, in any heat generating components such as integrated circuits of a variety of electronic products, light sources of LEDS or semi-conductor devices.

### BACKGROUND

Until early 2000's, heat spreader materials were made of aluminium and aluminium-based alloys. But the demand of lighter and more efficient material led to the development of graphite-based heat spreader material. The graphite can either be natural or synthetic. Natural graphite is mined while synthetic graphite can be produced by graphitizing a carbon-based material. However, the synthetic graphite differs from the natural one in that it can have a higher crystallinity degree and less impurities leading to a greater conductivity.

### SUMMARY OF THE INVENTION

However, an even greater quantity of heat needed to be dissipated led to thicker graphite-based heat spreader material. Unfortunately, the rule of thumb is that for synthetic graphite, greater is the thickness of the precursor film to be graphitized, lower is the crystalline degree of the final graphitized film and thus lower is its thermal conductivity. This means that, when the thickness of the precursor film is increased, the graphitization of the whole bulk material is less efficient.

Consequently, to increase the heat spread, a common approach has been to laminate two or more graphite-based layers using an adhesive film. However, such graphite laminates lead to the appearance of splices, wrinkles and bubbles leading to yield loss.

A goal of this invention is to increase the yield of such a graphite laminate. The present invention provides a method for manufacturing a heat spreader comprising the steps of
i. depositing an adhesive 1 on a major surface of at least one graphite layer 2, to obtain at least one graphite layer 2 coated by an adhesive layer 10, wherein
   a. said adhesive layer 10 has a thickness from 0.5 to 10 μm and comprises a solvent,
   b. said at least one graphite layer 2 has a thickness from 10 to 200 μm and has two opposed major surfaces,
ii. optionally positioning said at least one graphite layer coated by an adhesive layer on top of at least a further graphite layer 2 coated by an adhesive layer 10 so as to form a first stack of layers 3 alternating graphite layers and adhesive layers,
iii. positioning a graphite layer 20 having a thickness from 10 to 200 μm, on said first stack of layers 3 so as to form a second stack of layers 4, having a graphite layer as top and bottom layers
iv. compressing said second stack of layer 4 with a pressure from 7 to 20 MPa to form a graphite-based laminate 5,
v. heating said graphite-based laminate 5 such that the solvent of the adhesive is removed.

The present invention also provides a graphite laminate 6, manufactured as described above, comprising at least two graphite layers 200, having a thickness from 5 to 100 μm, and at least one adhesive layer 100, having a thickness from 1 to 5 μm, wherein
said at least two graphite layers 200 and said at least one adhesive layer 100 are disposed alternately on top of each other and
the top layer 7 and the bottom layer 8 of said graphite laminate are graphite layers.

### BRIEF DESCRIPTION OF THE DRAWINGS

FIG. 1 is an embodiment of the adhesive deposition step of the claimed process and FIG. 2 is an embodiment of two graphite layers coated by an adhesive layer

FIG. 3 is an embodiment of the positioning a graphite layer, on an adhesive layer on top of a first stack of layers so as to form a second stack of layers, having a graphite layer as top and bottom layers

FIG. 4 is an embodiment of the compressing step of the claimed process.

FIG. 5 is an embodiment of the heating step of the claimed process.

FIG. 6 is an embodiment of a graphite laminate manufactured by the claimed process.

FIG. 7 is a plot exhibiting the influence of the pressure on the thermal conductivity of a graphite laminate material.

### BRIEF DESCRIPTION

The invention also relates to a method for manufacturing a heat spreader comprising the steps of
i. depositing an adhesive 1 on a major surface of at least one graphite layer 2, to obtain at least one graphite layer coated by an adhesive layer, wherein
   a. said adhesive layer 10 has a thickness from 0.5 to 10 μm and comprises a solvent,
   b. said at least one graphite layer 2 has a thickness from 10 to 200 μm and has two opposed major surfaces,
ii. optionally positioning said at least one graphite layers coated by an adhesive layer on top of at least a further graphite layer 2 coated by an adhesive layer 10 so as to form a first stack of layers 3 alternating graphite layers and adhesive layers,
iii. positioning a graphite layer 20 having a thickness from 10 to 200 μm, on said first stack of layers 3 so as to form a second stack of layers 4, having a graphite layer as top and bottom layers
iv. compressing said second stack of layer 4 with a pressure from 7 to 20 MPa to form a graphite-based laminate 5,
v. heating said graphite-based laminate 5 such that the solvent of the adhesive is removed.

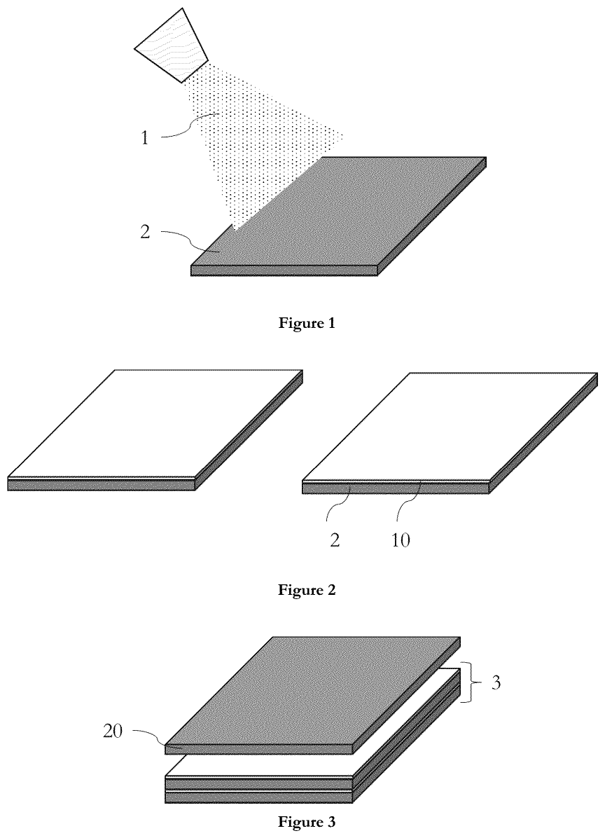

The deposition step, step i., is illustrated in FIG. 1 wherein an adhesive 1 is deposited on a major surface of a graphite layer 2 which result, as illustrated in FIG. 2, in at least one graphite layer 2 coated by an adhesive layer 10.

Preferably, in step i. the deposition is made by spraying. This can be done using an air spray gun, either fed by gravity or by a pump. The adhesive is then sprayed either manually or via automatic control with the parameters fixed according to the line of production requirements. Preferably, the air pressure is between 0.8 and 2 bar and it is selected according to the aperture of the needle for the adhesive feed.

Preferably, in step i. the deposition is made by rubbing an adhesive. This can be done by using a sponge or cloth soaked in adhesive, moved relatively with respect to the film in a longitudinal way and over its surface.

Alternatively, in step i., the deposition can be made by brushing and/or rolling and/or slot-die coating.

Preferably, in step i. said adhesive layer comprises organofunctional silanes and functionalized nanoscale SiO₂ particles. Even more preferably, in step i., said adhesive is composed of organofunctional silanes and functionalized, nanoscale SiO₂ particles. For example, said adhesive layer is a water-borne sol-gel system composed of organofunctional silanes and functionalized, nanoscale SiO₂ particles. Said adhesive can be mixed with water.

Alternatively, in step i., said adhesive layer can comprise aminofunctional silane being hydrolized before application.

Preferably, in step i., said adhesive layer has a thickness of from 0.5 to 5 μm. Preferably, in step i. said adhesive layer has a thickness from 1 μm to 5 μm

The at least one graphite layer may be any graphite in the form of a sheet or a foil that exhibits anisotropic thermal conductivity.

Preferably, in step i. said at least one graphite layer is made of compressed exfoliated natural graphite, pyrolytic graphite or heat treated graphitizable polymer. Even more preferably, said at least one graphite layer is made from heat treated polyimide. Even more preferably, said at least one graphite layer is made from graphene oxide. Forming processes of such graphite layer are well known by the skilled in the art.

Preferably, in step i. said at least one graphite layer has a thickness from 15 to 200 μm. Such thicker graphite layer increases the mechanical resistance and thus limit the breakage risk during the compressing of step iv.

Preferably, in step i. said at least one graphite layer has an in-plane thermal conductivity of at least 400 W·mK⁻¹, more advantageously of at least 1000 W·mK⁻¹, still more advantageously of at least 1400 W·mK⁻¹.

In another embodiment, in step i., said at least one graphite layer has an in-plane thermal conductivity from 400 to 2500 W·mK⁻¹.

Preferably, in step i. said at least one graphite layer is composed of 1 film. So, each graphite layer is composed of 1 film.

Alternatively, in step i. said at least one graphite layer is composed of 2 to 6 films. So, each graphite layer is composed of 2 to 6 films.

Preferably, in step i. an adhesive layer is deposited on one graphite layer. Preferably, in step i., an adhesive layer is deposited on two to seven graphite layers.

In the case where in step i., an adhesive is deposited on only one graphite layer, the step ii. can be skipped as the coated graphite layer forms the first stack of layers.

In step ii., which is optional, the at least one graphite layer coated by an adhesive layer obtain in step i. is positioned on top of at least a further graphite layer coated by an adhesive layer. For example, the at least one graphite layer obtained by an adhesive layer can be positioned on top of two graphite layers coated by an adhesive layer.

In step iii., as illustrated in FIG. 3, a graphite layer 20 is positioned on the first stack of layers 3. The graphite layer is positioned on an adhesive layer to form a stack of layers
alternating graphite layer and adhesive layer, and
having a graphite layer as top and bottom layers.

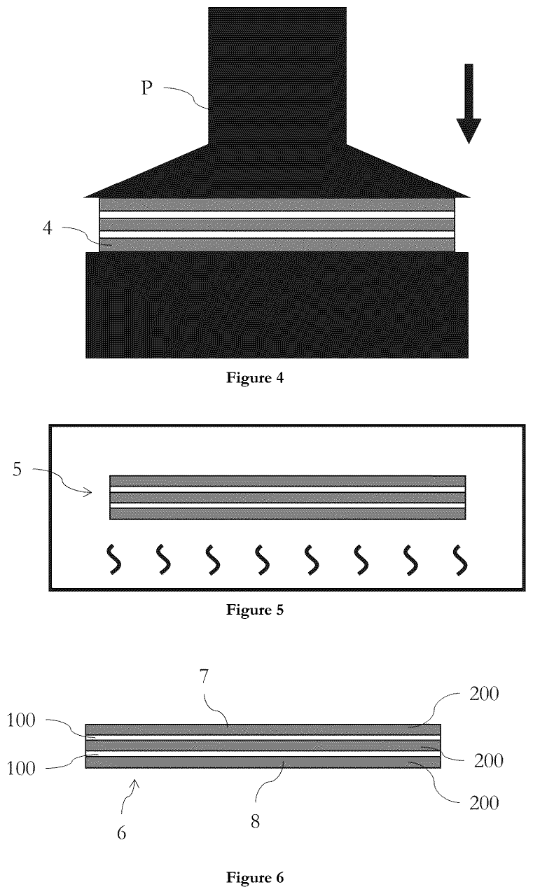

The step iv. is embodied in FIG. 4 wherein the second stack of layers 4 is compressed, by a press P.

Preferably, in step iv. said compression is done with a pressure from 10 to 16 MPa.

Preferably, in step iv. said compression is made by means of a press, preferably by means of a hydraulic press.

Preferably, in step iv. said compression is made by means of a roller.

The step v. aiming to remove the solvent is well known by any skilled in the art.

Preferably, in step v. said heating is done at a temperature from 50° C. to 150° C. Even more preferably, in step iv. said heating is done at a temperature from 70° C. to 130° C.

Preferably, in step v. said heating is done during 20 to 120 minutes. Even more preferably, in step iv. said heating is done during 30 to 60 minutes.

The invention, as illustrated in FIG. 6, also relates to a graphite laminate 6, manufactured as previously described, comprising at least two graphite layers 200, having a thickness from 5 to 100 μm, and at least one adhesive layer 100, having a thickness from 1 to 5 μm, wherein
said at least two graphite layers 200 and said at least one adhesive layer 100 are disposed alternately on top of each other and
the top layer 7 and the bottom layer 8 of said graphite laminate are graphite layers.

So, said graphite layers 200 and said adhesive layer 100 are disposed alternatively so as to form an alternance of graphite layer and of adhesive layer. This is illustrated in FIG. 6 wherein a graphite laminate comprises fives layers, three of graphite and two of adhesive and wherein a graphite layer is on top of an adhesive layer being on top of a graphite layer being on top of an adhesive layer being on top of a graphite layer.

Preferably, said graphite laminate comprises from two to seven graphite layers.

Preferably, said at least two graphite layers are made of compressed exfoliated natural graphite, pyrolytic graphite or heat treated graphitizable polymer.

Preferably, said at least two graphite layers have a thickness from 15 to 100 μm.

Preferably, said at least two graphite layers have an in-plane thermal conductivity from 400 to 2500 W·mK⁻¹.

The thickness of the adhesive layer of the graphite laminate differs from the thickness of the coated adhesive layer in step i. of the process due to the heating step (step v.) where the solvent of the adhesive is removed. Preferably, said at least one adhesive layer 100 has a thickness from 1 to 3 μm.

Preferably, said adhesive layer comprises organofunctional silanes and functionalized nanoscale SiO2 particles. Even more preferentially, said adhesive layer is composed of organofunctional silanes and functionalized nanoscale SiO2 particles.

The invention also relates to the use of said graphite laminate for a heat spreader device.

The heat spreader device can be used in electronic device, such as a mobile phone or a motherboard.

### EXPERIMENTAL RESULTS

Experimental trials have been conducted to assess the impact of the value of the net pressure during the step iii. of the claimed process.

For all trials, polyimide films having a thickness from 50 μm were graphitized. To do so, the polyimide films were carbonized by a heat treatment at 1000° C. in an inert atmosphere of N2 during 60 minutes to remove all the non-carbon groups of the polymer. Then the carbonized films were put in a graphitization furnace having an Ar inert atmosphere and underwent a heat treatment up to 2800° C. in order to rearrange the carbon atoms into the crystal lattice of graphite, thus obtaining graphite films of around 40 μm. After, the graphite films were rolled to reduce the porosity and increase their thermal conductivity. The resulting films have an in-plane thermal conductivity around 900 to 1000 W·mK land a thickness in the order of 25 μm.

For all trials, an adhesive layer of around 1 μm was deposited by spray coating on a first face of a graphite film, as illustrated in FIG. 1.

Then, the stack of layers was pressed by a hydraulic press forming a compressed stack of layers, as illustrated in FIG. 4. Different pressure values were tested, on different stack of layers, to determine the best range.

Then the compressed stack of layers was put into a furnace, at a temperature of 70° C. during 30 minutes to remove the adhesive solvent, as illustrated in FIG. 6.

Ultimately, the in-plane thermal conductivity was measured using as the “Thermal Bridge Method” described in Yifeng Fu et al 2020 2D Mater. 7 012001.

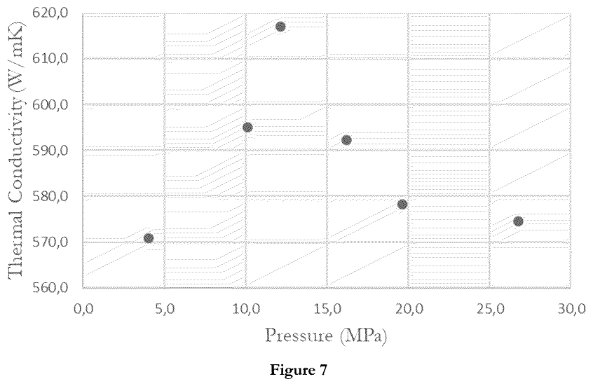

The results of the experiments are plotted in FIG. 7 wherein the in-plane thermal conductivity is plotted in function of the pressure applied on the compressed stack of layers.

It is clear that the value of the pressure has an impact on the in-plane conductivity of the graphite laminate and that the best range is for a pressure value from 7 to 20 MPa.

What is claimed is:

1-14. (canceled)

15: A method for manufacturing a heat spreader, the method comprising the steps of:
i. depositing an adhesive on a major surface of at least one graphite layer, to obtain at least one graphite layer coated by an adhesive layer, wherein the adhesive layer has a thickness from 0.5 to 10 μm and includes a solvent, and the at least one graphite layer has a thickness from 10 to 200 μm and has two opposed major surfaces,
ii. optionally positioning the at least one graphite layer coated by the adhesive layer on top of at least a further graphite layer coated by a further adhesive layer so as to define a first stack of layers with alternating graphite layers and adhesive layers,
iii. positioning a yet further graphite layer having a thickness from 10 to 200 μm, on the first stack of layers or on the at least one graphite layer coated by the adhesive layer on top on the so as to define a second stack of layers having top and bottom graphite layers,
iv. compressing the second stack of layers with a pressure from 7 to 20 MPa to define a graphite-based laminate,
v. heating the graphite-based laminate such that the solvent of the adhesive is removed.

16: The method as recited in claim 15 wherein, in step i. the deposition is made by spraying an adhesive.

17: The method as recited in claim 15 wherein, in step i. the deposition is made by rubbing an adhesive.

18: The method as recited in claim 15 wherein, in step i. the adhesive layer comprises organofunctional silanes and functionalized nanoscale SiO2 particles.

19: The method as recited in claim 15 wherein, in step i. said adhesive layer has a thickness from 1 to 5 μm.

20: The method as recited in claim 15 wherein, in step i. the at least one graphite layer is made of compressed exfoliated natural graphite, pyrolytic graphite or heat treated graphitizable polymer.

21: The method as recited in claim 15 wherein, in step i. the at least one graphite layer 2 has a thickness from 15 to 200 μm.

22: The method as recited in claim 15 wherein, in step i. the at least one graphite layer 2 has an in-plane thermal conductivity from 400 to 2500 W·mK⁻¹.

23: The method as recited in claim 15 wherein, in step iii. the compression is made by a roller.

24: The method as recited in claim 15 wherein, in step iii. the compression is made by a press.

25: The method as recited in claim 24 wherein the press is a hydraulic press.

26: The method as recited in claim 15 wherein, in step iii. the compression is done with a pressure from 10 to 16 MPa.

27: A graphite laminate, manufactured as recited in claim 15, comprising at least two graphite layers, each having a thickness from 5 to 100 μm, and at least one adhesive layer having a thickness from 1 to 5 μm, wherein the at least two graphite layers and the at least one adhesive layer are disposed alternately on top of each other and a top layer and a bottom layer of the graphite laminate are from the at least two graphite layers.

28: A graphite laminate as recited in claim 27 wherein the at least two graphite layers numbers from two to seven.

29: A method for using the graphite laminate as recited in claim 16 comprising using the graphite laminate in a heat spreader.
